(19) United States
(12) Patent Application Publication
(10) Pub. No.: US 2024/0306454 A1
(43) Pub. Date: Sep. 12, 2024

(54) DISPLAY DEVICE

(71) Applicant: Samsung Display Co., LTD., Yongin-si (KR)

(72) Inventor: CHUL HYUN CHOI, Yongin-si (KR)

(21) Appl. No.: 18/517,250

(22) Filed: Nov. 22, 2023

(30) Foreign Application Priority Data
Mar. 7, 2023 (KR) 10-2023-0029951

(51) Int. Cl. H10K 59/131; H10K 59/80

(52) U.S. Cl. CPC H10K 59/131; H10K 59/8793

(57) ABSTRACT

A display device includes a substrate including a light emitting area and a non-light emitting area surrounding the light emitting area, a conductive line on the substrate to pass through the light emitting area and including an overlapping portion overlapping the light emitting area, and a pixel electrode on the conductive line and overlapping the overlapping portion of the conductive line. The overlapping portion of the conductive line includes a body part having a polygonal planar shape and having an area smaller than an area of the light emitting area, a first protrusion part protruding in a first direction from the body part to a boundary between the light emitting area and the non-light emitting area, and a second protrusion part protruding in a second direction opposite to the first direction from the body part to the boundary between the light emitting area and the non-light emitting area.

This application claims priority to Korean Patent Application No. 10-2023-0029951, filed on Mar. 7, 2023, and all the benefits accruing therefrom under 35 U.S.C. § 119, the content of which in its entirety is herein incorporated by reference.

### BACKGROUND

### 1. Field

The disclosure relates to a display device. More specifically, the disclosure relates to a display device for displaying visual information.

### 2. Description of the Related Art

As information technology develops, the importance of a display device as a connection medium between a user and information is being highlighted. For example, the use of display devices such as a liquid crystal display device (LCD), an organic light emitting display device (OLED), a plasma display device (PDP), a quantum dot display device or the like is increasing.

Such a display device typically includes a substrate, a plurality of conductive lines disposed on the substrate, and a light emitting element disposed on the conductive lines, and research on the structure, shape, and arrangement of the conductive lines to improve display quality is ongoing.

### SUMMARY

Embodiments provide a display device with improved display quality.

A display device according to an embodiment includes a substrate including a light emitting area and a non-light emitting area surrounding the light emitting area, a conductive line disposed on the substrate to pass through the light emitting area in a plan view, where the conductive line includes an overlapping portion overlapping the light emitting area, and a pixel electrode disposed on the conductive line and at least partially overlapping the overlapping portion of the conductive line, where the overlapping portion of the conductive line includes a body part having a polygonal planar shape and having an area smaller than an area of the light emitting area in the plan view, a first protrusion part protruding in a first direction from the body part to a boundary between the light emitting area and the non-light emitting area in the plan view, and a second protrusion part protruding in a second direction opposite to the first direction from the body part to the boundary between the light emitting area and the non-light emitting area in the plan view.

In an embodiment, the first protrusion part and the second protrusion part may be opposite to each other with a center point of the body part therebetween.

In an embodiment, the overlapping portion of the conductive line may be point symmetric with respect to the center point of the body part.

In an embodiment, the pixel electrode may overlap an edge of the body part in the plan view, and a portion of an upper surface of the pixel electrode adjacent to an edge of the body part from which the first protrusion part protrudes and a portion of the upper surface of the pixel electrode adjacent to an edge of the body part from which the second protrusion part protrudes may be substantially flat.

In an embodiment, a portion of an upper surface of the pixel electrode adjacent to an edge of the body part where the first protrusion part and the second protrusion part do not protrude may have a stepped structure.

In an embodiment, the display device may further include a first via insulating layer and a second via insulating layer, which are disposed between the substrate and the pixel electrode, and a lower conductive layer disposed between the substrate and the first via insulating layer, and the conductive line may be disposed between the first via insulating layer and the second via insulating layer, and is electrically connected to the pixel electrode through a contact hole defined in the second via insulating layer.

In an embodiment, the conductive line may be electrically connected to the lower conductive layer through a contact hole formed in the first via insulating layer.

In an embodiment, the conductive line may include a data line which transmits a data voltage, a power supply voltage line which transmits a power supply voltage, and an initialization voltage line which transmits an initialization voltage.

In an embodiment, the display device may further include a light emitting layer disposed on the pixel electrode, a common electrode disposed on the light emitting layer, and a polarization layer disposed on the common electrode.

A display device according to an embodiment includes a substrate including a light emitting area and a non-light emitting area surrounding the light emitting area, a conductive line disposed on the substrate to pass through the light emitting area in a plan view, where the conductive line includes an overlapping portion overlapping the light emitting area, and a pixel electrode disposed on the conductive line and at least partially overlapping the overlapping portion of the conductive line, where the overlapping portion of the conductive line includes a body part having an octagonal planar shape and having an area smaller than an area of the light emitting area in the plan view, a first protrusion part protruding in a first direction from a first edge of the body part to a boundary between the light emitting area and the non-light emitting area in the plan view, and a second protrusion part protruding in a second direction opposite to the first direction from a second edge of the body part to the boundary between the light emitting area and the non-light emitting area in the plan view.

In an embodiment, the first edge and the second edge may be opposite to each other with a center point of the body part therebetween.

In an embodiment, the overlapping portion of the conductive line may be point symmetric with respect to the center point of the body part.

In an embodiment, the body part may include a third edge located in a third direction perpendicular to both of the first direction and the second direction from the center point, a fourth edge located in a fourth direction opposite to the third direction from the center point and opposite to the third edge with the center point therebetween, a fifth edge connecting the first edge and the third edge, a sixth edge connecting the second edge and the fourth edge and opposite to the fifth edge with the center point therebetween, a seventh edge connecting the first edge and the fourth edge, and an eighth edge connecting the second edge and the third edge and opposite to the seventh edge with the center point therebetween.

In an embodiment, a first imaginary line extending from the center point to the first edge and substantially perpendicular to the first edge may be inclined by about 45 degrees in a counterclockwise direction from a second imaginary line extending from the center point to the seventh edge and substantially perpendicular to the seventh edge in the plan view, and a third imaginary line extending from the center point to the second edge and substantially perpendicular to the second edge may be inclined by about 45 degrees in the counterclockwise direction from a fourth imaginary line extending from the center point to the eighth edge and substantially perpendicular to the eighth edge in the plan view.

In an embodiment, a fifth imaginary line extending from the center point to the third edge and substantially perpendicular to the third edge may be inclined by about 45 degrees in a clockwise direction from a fourth imaginary line extending from the center point to the eighth edge and substantially perpendicular to the eighth edge in the plan view, and a sixth imaginary line extending from the center point to the fourth edge and substantially perpendicular to the fourth edge may be inclined by about 45 degrees in the clockwise direction from a second imaginary line extending from the center point to the seventh edge and substantially perpendicular to the seventh edge in the plan view.

In an embodiment, the pixel electrode may overlap the first to eighth edges in the plan view, and a portion of an upper surface of the pixel electrode adjacent to the first edge and a portion of the upper surface of the pixel electrode adjacent to the second edge may be substantially flat.

In an embodiment, each of portions of an upper surface of the pixel electrode adjacent to the third to eighth edges, respectively, may have a stepped structure.

In an embodiment, the display device may further include a first via insulating layer and a second via insulating layer, which are disposed between the substrate and the pixel electrode and a lower conductive layer disposed between the substrate and the first via insulating layer, and the conductive line may be disposed between the first via insulating layer and the second via insulating layer, electrically connected to the pixel electrode through a contact hole defined in the second via insulating layer, and electrically connected to the lower conductive layer through a contact hole defined in the first via insulating layer.

In an embodiment, the conductive line may include a data line which transmits a data voltage, a power supply voltage line which transmits a power supply voltage, and an initialization voltage line which transmits an initialization voltage.

In an embodiment, the display device may further include a light emitting layer disposed on the pixel electrode, a common electrode disposed on the light emitting layer, and a polarization layer disposed on the common electrode.

The display device according to embodiments may include a conductive line disposed below a pixel electrode. In such embodiments, the conductive line may pass through a light emitting area and have an overlapping portion overlapping the light emitting area in a plan view. In such embodiments, the overlapping portion may have a body part, a first protrusion part, and a second protrusion part, the body part may have an area smaller than an area of the light emitting area corresponding, and the first protrusion part and the second protruding part may protrude in opposite directions from the body part to a boundary between the light emitting area and a non-light emitting area, respectively.

Accordingly, in such embodiments, each of portions of an upper surface of the pixel electrode adjacent to an edge of the body part from which the first protrusion part protrudes and an edge of the body part from which the second protrusion part protrudes, respectively, may be substantially flat, while a portion of the upper surface of the pixel electrode adjacent to an edge of the body part where the first protrusion part and the second protrusion part do not protrude may have a stepped structure.

That is, according to embodiments, a profile of the upper surface of the pixel electrode in the light emitting area may be adjusted by adjusting a direction in which each of the first protrusion part and the second protrusion part protrude from the body part. Accordingly, a luminance ratio of light emitted from the pixel electrode may be adjusted for each azimuth angle. Therefore, even after the polarization layer is disposed on the light emitting element, luminance non-uniformity or color shift non-uniformity by azimuth angles caused by the polarization layer may be substantially decreased or effectively prevented, thereby improving display quality of the display device.

It is to be understood that both the foregoing general description and the following detailed description are exemplary and explanatory and are intended to provide further explanation of the invention as claimed.

### BRIEF DESCRIPTION OF THE DRAWINGS

Illustrative, non-limiting embodiments will be more clearly understood from the following detailed description taken in conjunction with the accompanying drawings.

FIG. 1 is a plan view illustrating a display device according to an embodiment.

FIG. 2 is a circuit diagram illustrating a pixel included in the display device of FIG. 1.

FIG. 3 is a plan view schematically illustrating a display area of the display device of FIG. 1.

FIG. 4 is an enlarged view illustrating an enlarged second light emitting area of the display device of FIG. 3 according to an embodiment.

FIG. 5 is a cross-sectional view taken along line I-I′ of FIG. 4.

FIG. 6 is a cross-sectional view taken along line II-II′ of FIG. 4.

FIG. 7 is an enlarged view illustrating an enlarged second light emitting area of the display device of FIG. 1 according to an alternative embodiment.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the claims.

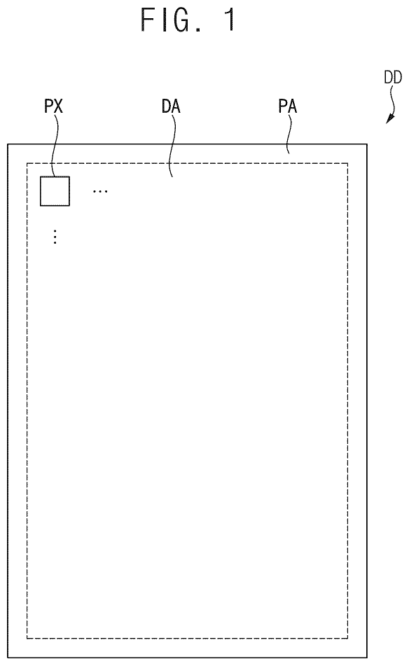

FIG. 1 is a plan view illustrating a display device according to an embodiment.

Referring to FIG. 1, a display device DD according to an embodiment may be divided into a display area DA and a peripheral area PA. The display area DA may display an image, and the peripheral area PA may be located around the display area DA. In an embodiment, for example, the peripheral area PA may surround the display area DA.

In an embodiment, the display device DD may have a rectangular planar shape. However, the invention is not necessarily limited thereto, and the display device DD may have various planar shapes according to embodiments.

At least one pixel PX may be disposed in the display area DA, and an image may be displayed through the pixel PX in the display area DA. The pixel PX may include a driving element (e.g., a transistor) and a light emitting element (e.g., an organic light emitting diode) connected to the driving element. The light emitting element may emit light by receiving a signal and/or voltage from the driving element. In an embodiment, for example, the driving element may provide a driving current to the light emitting element, and the light emitting element may generate light having a luminance corresponding to the driving current. The pixel PX may be generally disposed in the display area DA. In an embodiment, for example, the pixel PX may be arranged in a matrix form in the display area DA.

A driver for driving the pixel PX may be disposed in the peripheral area PA. The driver may include a data driver, a gate driver, an emission driver, a power voltage generator, a timing controller, or the like. The driver may provide the signal and/or the voltage to the pixel PX.

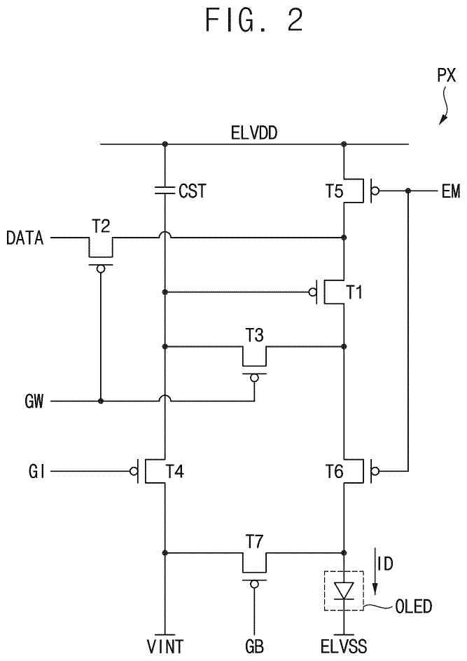

FIG. 2 is a circuit diagram illustrating a pixel included in the display device of FIG. 1.

Referring to FIG. 2, an embodiment of the pixel PX may include a first transistor T1, a second transistor T2, a third transistor T3, a fourth transistor T4, a fifth transistor T5, a sixth transistor T6, a seventh transistor T7, a storage capacitor CST, and an organic light emitting diode OLED.

The first transistor T1 may include a gate terminal, a first terminal, and a second terminal. The gate terminal of the first transistor T1 may be connected to the storage capacitor CST. The first terminal of the first transistor T1 may be connected to the second transistor T2. The second terminal of the first transistor T1 may be connected to the sixth transistor T6. The first transistor T1 may generate a driving current ID based on a voltage difference between the gate terminal of the first transistor T1 and the first terminal of the first transistor T1. In such an embodiment, the first transistor T1 may be referred to as a driving transistor.

The second transistor T2 may include a gate terminal, a first terminal, and a second terminal. The gate terminal of the second transistor T2 may receive a first gate signal GW. The second transistor T2 may be turned on or off in response to the first gate signal GW. The first terminal of the second transistor T2 may receive the data voltage DATA. The second transistor T2 of the second transistor T2 may provide a data voltage DATA to the first terminal of the first transistor T1 in response to the first gate signal GW. In such an embodiment, the second transistor T2 may be referred to as a switching transistor.

The third transistor T3 may include a gate terminal, a first terminal, and a second terminal. The gate terminal of the third transistor T3 may receive the first gate signal GW. The first terminal of the third transistor T3 may be connected to the gate terminal of the first transistor T1. The second terminal of the third transistor T3 may be connected to the second terminal of the first transistor T1. The third transistor T3 may compensate for the threshold voltage of the first transistor T1. In such an embodiment, the third transistor T3 may be referred to as a compensation transistor.

The fourth transistor T4 may include a gate terminal, a first terminal, and a second terminal. The gate terminal of the fourth transistor T4 may receive a second gate signal GI. The first terminal of the fourth transistor T4 may be connected to the gate terminal of the first transistor T1. The second terminal of the fourth transistor T4 may receive an initialization voltage VINT. The fourth transistor T4 may initialize the gate terminal of the first transistor T1.

The fifth transistor T5 may include a gate terminal, a first terminal, and a second terminal. The gate terminal of the fifth transistor T5 may receive an emission control signal EM. The first terminal of the fifth transistor T5 may receive a high power supply voltage ELVDD. The second terminal of the fifth transistor T5 may be connected to the first transistor T1.

The sixth transistor T6 may include a gate terminal, a first terminal, and a second terminal. The gate terminal of the sixth transistor T6 may receive the emission control signal EM. The first terminal of the sixth transistor T6 may be connected to a first transistor T1. The second terminal of the sixth transistor T6 may be connected to the organic light emitting diode OLED. The sixth transistor T6 may transmit a driving current ID to the organic light emitting diode OLED in response to the emission control signal EM.

The seventh transistor T7 may include a gate terminal, a first terminal, and a second terminal. The gate terminal of the seventh transistor T7 may receive a third gate signal GB. The first terminal of the seventh transistor T7 may be connected to the organic light emitting diode OLED. The second terminal of the seventh transistor T7 may receive an initialization voltage VINT. The seventh transistor T7 may initialize the organic light emitting diode OLED.

The storage capacitor CST may include a first terminal and a second terminal. The first terminal of the storage capacitor CST may receive the high power supply voltage ELVDD. The second terminal of the storage capacitor CST may be connected to the gate terminal of the first transistor T1.

The organic light emitting diode OLED may include a first terminal and a second terminal. The first terminal of the organic light emitting diode OLED may be connected to the sixth transistor T6. The second terminal of the organic light emitting diode OLED may receive a low power supply voltage ELVSS. The organic light emitting diode OLED may emit light based on the driving current ID.

A connection structure of the pixel PX shown in FIG. 2 is only example and may be variously changed modified according to embodiments. In an alternative embodiment, for example, the pixel PX may include less than six transistors or more than eight transistors. Also, the pixel PX may include two or more capacitors.

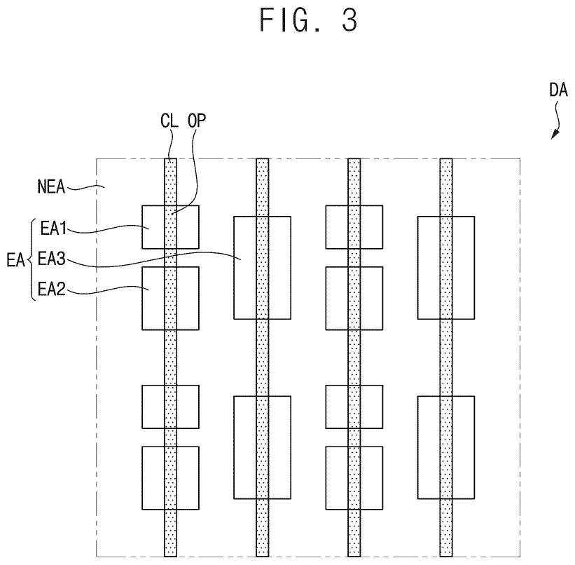

FIG. 3 is a plan view schematically illustrating a display area of the display device of FIG. 1.

Referring to FIGS. 1 and 3, an embodiment of the display area DA may include a light emitting area EA and a non-light emitting area NEA surrounding the light emitting area EA. The light emitting area EA may include a first light emitting area EA1, a second light emitting area EA2, and a third light emitting area EA3. In an embodiment, for example, the first light emitting area EA1 may emit red light, the second light emitting area EA2 may emit green light, and the third light emitting area EA3 may emit blue light. However, the invention is not necessarily limited thereto.

In an embodiment, an arrangement structure of the first to third light emitting areas EA1, EA2, and EA3 may be an S-stripe structure. In an embodiment, for example, the first light emitting area EA1 and the second light emitting area EA2 may be disposed in a first column, and the third light emitting area EA3 may be disposed in a second column adjacent to the first column. However, the arrangement structure of the first to third light emitting areas EA1, EA2, and EA3 is not necessarily limited thereto.

In an embodiment, a conductive line CL may be disposed in the display area DA. The conductive line CL may include a data line that transfers the data voltage DATA (see in FIG. 2) to the pixel PX, a power supply voltage line that transfers the high power supply voltage ELVDD (see in FIG. 2), and/or an initialization voltage line that transfers the initialization voltage VINT (see in FIG. 2). However, the invention is not necessarily limited thereto.

In an embodiment, the conductive line CL may extend to pass through the light emitting area EA in a plan view or when viewed in a thickness direction of the display device DD. That is, at least a portion of the conductive line CL may overlap the light emitting area EA in the plan view. Hereinafter, a portion of the conductive line CL overlapping the light emitting area EA may be defined as an overlapping portion OP. That is, the conductive line CL may include the overlapping portion OP overlapping the light emitting area EA.

A shape and an arrangement of the conductive line CL illustrated in FIG. 3 only example and may be variously changed according to embodiments.

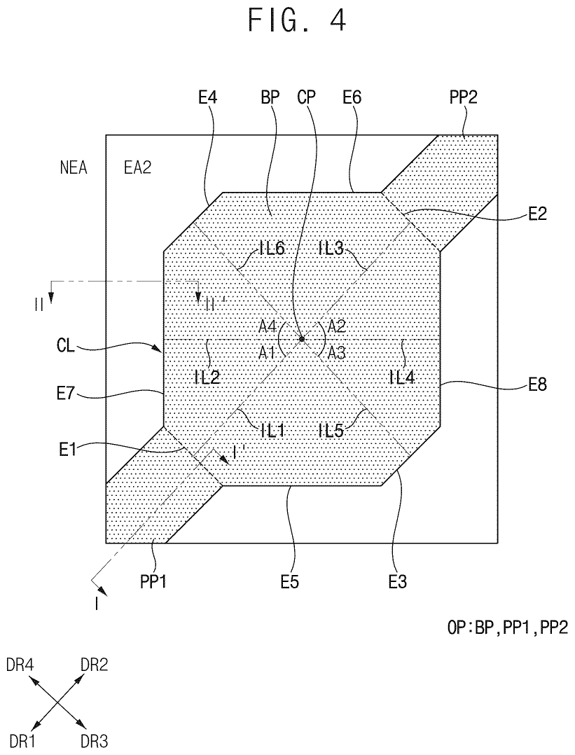

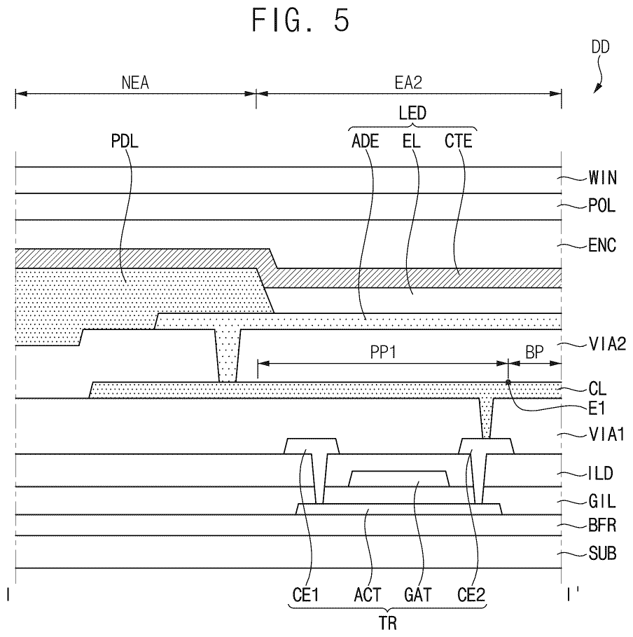

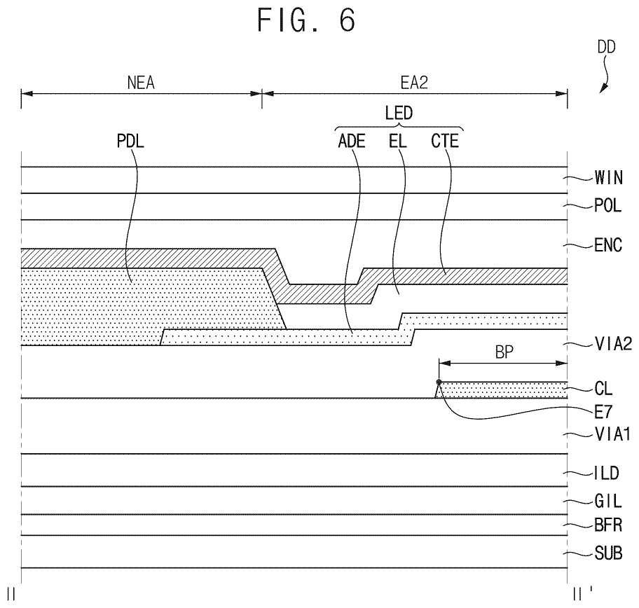

FIG. 4 is an enlarged view illustrating an enlarged second light emitting area of the display device of FIG. 3 according to an embodiment, FIG. 5 is a cross-sectional view taken along line I-I′ of FIG. 4, and FIG. 6 is a cross-sectional view taken along line II-II′ of FIG. 4.

In FIGS. 4 to 6, only a planar structure and cross-sectional structure of the second light emitting area EA2 are illustrated as an example for convenience of description. A planar structure and a cross-sectional structure of each of the first and third light emitting areas EA1 and EA3 may be substantially the same as those of the second light emitting area EA2, and any repetitive detailed description thereof will be omitted.

Referring to FIGS. 4 to 6, an embodiment of the display device DD may include a substrate SUB, a buffer layer BFR, a driving element TR, a gate insulating layer GIL, an interlayer insulating layer ILD, a first via insulating layer VIA1, the conductive line CL, a second via insulating layer VIA2, a pixel defining layer PDL, a light emitting element LED, an encapsulation layer ENC, a polarization layer POL, and a window WIN.

The driving element TR may include an active pattern ACT, a gate electrode GAT, a first connection electrode CE1 and a second connection electrode CE2. The driving element TR may correspond to any one of the first to seventh transistors T1, T2, T3, T4, T5, T6, and T7 described with reference to FIG. 2. The light emitting element LED may include a pixel electrode ADE, a light emitting layer EL, and a common electrode CTE. The light emitting element LED may correspond to the organic light emitting diode OLED described with reference to FIG. 2.

The substrate SUB may include a transparent or opaque material. In an embodiment, examples of materials that can be used as the substrate SUB may include glass, quartz, plastic, or the like. These may be used alone or in combination with each other.

The buffer layer BFR may be disposed on the substrate SUB. The buffer layer BFR may prevent diffusion of impurities such as oxygen, moisture, or the like to an upper portion of the substrate SUB through the substrate SUB. The buffer layer BFR may include an inorganic insulating material such as a silicon compound or a metal oxide.

The active pattern ACT may be disposed on the buffer layer BFR. In an embodiment, the active pattern ACT may include a silicon semiconductor material or an oxide semiconductor material. Examples of the silicon semiconductor material that can be used as the active pattern ACT may include amorphous silicon, polycrystalline silicon, or the like.

In an embodiment, the gate insulating layer GIL may be disposed on the buffer layer BFR. The gate insulating layer GIL may cover the active pattern ACT. In an alternative embodiment, the gate insulating layer GIL may be disposed on the active pattern ACT in a pattern form to expose a portion of the active pattern ACT. In an embodiment, for example, the gate insulating layer GIL may be disposed on the active pattern ACT in a pattern form to overlap the gate electrode GAT. The gate insulating layer GIL may include an inorganic insulating material.

The gate electrode GAT may be disposed on the gate insulating layer GIL. In an embodiment, the gate electrode GAT may include a metal, an alloy, a conductive metal oxide, a transparent conductive material, or the like.

The interlayer insulating layer ILD may be disposed on the gate insulating layer GIL. In an embodiment, the interlayer insulating layer ILD may cover the gate electrode GAT. The interlayer insulating layer ILD may include an inorganic insulating material.

The first connection electrode CE1 and the second connection electrode CE2 may be disposed on the interlayer insulating layer ILD. The first connection electrode CE1 and the second connection electrode CE2 may be electrically connected to the active pattern ACT through contact holes defined or formed in the interlayer insulating layer ILD and the gate insulating layer GIL, respectively. Each of the first connection electrode CE1 and the second connection electrode CE2 may include a metal, an alloy, a conductive metal oxide, a transparent conductive material, or the like.

In an embodiment, a conductive layer including the first connection electrode CE1 and the second connection electrode CE2 may be referred to as a lower conductive layer. That is, the lower conductive layer may be disposed between the interlayer insulating layer ILD and the first via insulating layer VIA1.

The first via insulating layer VIA1 may be disposed on the interlayer insulating layer ILD. The first via insulating layer VIA1 may cover the first connection electrode CE1 and the second connection electrode CE2. In such an embodiment, the first via insulating layer VIA1 may cover the lower conductive layer. The first via insulating layer VIA1 may include an organic insulating material.

The conductive line CL may be disposed on the first via insulation layer VIA1. In an embodiment, the conductive line CL may include a metal, an alloy, a conductive metal oxide, a transparent conductive material, or the like.

In an embodiment, the conductive line CL may be electrically connected to the lower conductive layer through a contact hole defined or formed in the first via insulating layer VIA1. In an embodiment, for example, as shown in FIG. 5, the conductive line CL may be electrically connected to the second connection electrode CE2. However, the invention is not necessarily limited thereto.

In an embodiment, as described above, the conductive line CL may include or define the data line, the power supply voltage line, and/or the initialization voltage line. In such an embodiment, the conductive line CL may include the overlapping portion OP overlapping the light emitting area EA.

In an embodiment, as shown in FIG. 4, the overlapping portion OP of the conductive line CL may include a body part BP, a first protrusion part PP1, and a second protrusion part PP2. In an embodiment, the body part BP, the first protrusion part PP1, and the second protrusion part PP2 may be integrally connected or integrally formed with each other as a single unitary and indivisible part.

In an embodiment, the body part BP may have a polygonal planar shape. In an embodiment, for example, as shown in FIG. 4, the body part BP may have an octagonal planar shape. However, the invention is not necessarily limited thereto, and the body part BP may have a polygonal planar shape other than an octagonal planar shape. Hereinafter, for convenience of description, embodiments in which the body part BP has an octagonal planar shape will be described.

In an embodiment, an area of the body part BP may be smaller than an area of the second light emitting area EA2. That is, the body part BP may be located inside a boundary between the second light emitting area EA2 and the non-light emitting area NEA in the plan view. In an embodiment, although not shown, an area of a body part of an overlapping portion overlapping the first light emitting area EA1 (see in FIG. 3) may be smaller than an area of the first light emitting area EA1. In such an embodiment, an area of a body part of an overlapping portion overlapping the third light emitting area EA3 (see in FIG. 3) may be smaller than an area of the third light emitting area EA3.

In an embodiment, the body part BP may be point symmetric with respect to a center point CP of the body part BP. That is, when the body part BP is rotated about the center point CP by 180 degrees, the shape of the body part BP is identical to its original. In an embodiment, the body part BP may have first to eighth edges E1, E2, E3, E4, E5, E6, E7, and E8. In an embodiment, for example, in the plan view, the first edge E1 may be located in a first direction DR1 from the center point CP, and the second edge E2 may be located in a second direction DR2 opposite to the first direction DR1 from the center point CP. That is, the first edge E1 and the second edge E2 may face each other with the center point CP therebetween.

In such an embodiment, the third edge E3 may be located in a third direction DR3 perpendicular to both of the first and second directions DR1 and DR2 from the center point CP, and the fourth edge E4 may be located in a fourth direction DR4 opposite to the third direction DR3 from the center point CP. That is, the third edge E3 and the fourth edge E4 may face each other with the center point CP therebetween.

In such an embodiment, the fifth edge E5 may connect the first edge E1 and the third edge E3 (i.e., connected between the first edge E1 and the third edge E3), and the sixth edge E6 may connect the second edge E2 and the fourth edge E4. That is, the fifth edge E5 and the sixth edge E6 may face each other with the center point CP therebetween.

In such an embodiment, the seventh edge E7 may connect the first edge E1 and the fourth edge E4, and the eighth edge E8 may connect the second edge E2 and the third edge E3. That is, the seventh edge E7 and the eighth edge E8 may face each other with the center point CP therebetween.

In an embodiment, first to sixth imaginary lines IL1, IL2, IL3, IL4, IL5, and IL6 may be defined on the body part BP in a plan view. In an embodiment, for example, the first imaginary line IL1 may extend from the center point CP to the first edge E1 and may be substantially perpendicular to the first edge E1. Also, the second imaginary line IL2 may extend from the center point CP to the seventh edge E7 and may be substantially perpendicular to the seventh edge E7. Also, the third imaginary line IL3 may extend from the center point CP to the second edge E2 and may be substantially perpendicular to the second edge E2. Also, the fourth imaginary line IL4 may extend from the center point CP to the eighth edge E8 and may be substantially perpendicular to the eighth edge E8. Also, the fifth imaginary line IL5 may extend from the center point CP to the third edge E3 and may be substantially perpendicular to the third edge E3. Also, the sixth imaginary line IL6 may extend from the center point CP to the fourth edge E4 and may be substantially perpendicular to the fourth edge E4.

In an embodiment, in a plan view, the first imaginary line IL1 may be inclined by about 45 degrees in a counterclockwise direction from the second imaginary line IL2. That is, a first angle A1 formed by the first imaginary line IL1 and the second imaginary line IL2 in a plan view may be about 45 degrees.

Also, in a plan view, the third imaginary line IL3 may be inclined by about 45 degrees in the counterclockwise direction from the fourth imaginary line IL4. That is, a second angle A2 formed by the third imaginary line IL3 and the fourth imaginary line IL4 in a plan view may be about 45 degrees. In other words, the third imaginary line IL3 may be inclined by about 225 degrees in the counterclockwise direction from the second imaginary line IL2.

Also, in a plan view, the fifth imaginary line IL5 may be inclined in a clockwise direction by about 45 degrees from the fourth imaginary line IL4. That is, a third angle A3 formed by the fifth imaginary line IL5 and the fourth imaginary line IL4 in a plan view may be about 45 degrees. In other words, the fifth imaginary line IL5 may be inclined by about 135 degrees in the counterclockwise direction from the second imaginary line IL2.

Also, in a plan view, the sixth imaginary line IL6 may be inclined in the clockwise direction by about 45 degrees from the second imaginary line IL2. That is, a fourth angle A4 formed by the sixth imaginary line IL6 and the second imaginary line IL2 in a plan view may be about 45 degrees. In other words, the sixth imaginary line IL6 may be inclined by about 315 degrees in the counterclockwise direction from the second imaginary line IL2.

In an embodiment, the first protrusion part PP1 may protrude from the first edge E1 to the boundary between the second light emitting area EA2 and the non-light emitting area NEA. That is, the first protrusion part PP1 may protrude toward the first direction DR1 from the first edge E1 of the body part BP.

In a plan view, the overlapping portion OP of the conductive line CL may be connected to the boundary between the second light emitting area EA2 and the non-light emitting area NEA by the first protrusion part PP1. In an embodiment, the overlapping portion OP of the conductive line CL may be connected to the boundary between the second light emitting area EA2 and the non-light emitting area NEA by the first protrusion part PP1 in the first direction DR1 from the center point CP of the body part BP. That is, the conductive line CL may be located between the first edge E1 and the boundary between the second light emitting area EA2 and the non-light emitting area NEA.

In such an embodiment, the second protrusion part PP2 may protrude from the second edge E2 to the boundary between the second light emitting area EA2 and the non-light emitting area NEA. That is, the second protrusion part PP2 may protrude toward the second direction DR2 from the second edge E2 of the body part BP. Accordingly, the first protrusion part PP1 and the second protrusion part PP2 may be opposite to each other with the center point CP therebetween. In an embodiment, for example, the overlapping portion OP may be point symmetric with respect to the center point CP.

In a plan view, the overlapping portion OP of the conductive line CL may be connected to the boundary between the second light emitting area EA2 and the non-light emitting area NEA by the second protrusion part PP2. In an embodiment, the overlapping portion OP of the conductive line CL may be connected to the boundary between the second light emitting area EA2 and the non-light emitting area NEA by the second protrusion part PP2 in the second direction DR2 from the center point CP of the body part BP. That is, the conductive line CL may be located between the second edge E2 and the boundary between the second light emitting area EA2 and the non-light emitting area NEA.

In an embodiment, separate protrusion parts may not protrude from the third to eighth edges E3, E4, E5, E6, E7, and E8. That is, the conductive line CL may not be located between the third to eighth edges E3, E4, E5, E6, E7, and E8 and the boundary between the second light emitting area EA2 and the non-light emitting area NEA.

In an embodiment, as shown in FIG. 5, the second via insulating layer VIA2 may be disposed on the conductive line CL. The second via insulating layer VIA2 may cover the conductive line CL. That is, the conductive line CL may be disposed between the first via insulating layer VIA1 and the second via insulating layer VIA2. The second via insulating layer VIA2 may include an organic insulating material.

The pixel electrode ADE may be disposed on the second via insulating layer VIA2. In an embodiment, as shown in FIG. 5, the pixel electrode ADE may be electrically connected to the conductive line CL through a contact hole defined or formed in the second via insulating layer VIA2. In an embodiment, the pixel electrode ADE may include a metal, an alloy, a conductive metal oxide, a transparent conductive material, or the like.

The pixel defining layer PDL may be disposed on the pixel electrode ADE. The pixel defining layer PDL may include an organic insulating material. A pixel opening exposing at least a portion of the pixel electrode ADE may be defined through the pixel defining layer PDL. An light emitting area and a non-light emitting area of the display device DD may be defined by the pixel opening. In an embodiment, for example, as shown in FIGS. 5 and 6, a portion where the pixel opening is located may correspond to the second light emitting area EA2, and a portion where the pixel defining layer PDL is disposed may correspond to the non-light emitting area NEA.

In an embodiment, for example, a portion of the pixel electrode ADE may be entirely disposed in the second light emitting area EA2. Accordingly, the pixel electrode ADE may overlap the overlapping portion OP of the conductive line CL in a plan view. in an embodiment, the pixel electrode ADE may overlap the body part BP of the conductive line CL in a plan view. In such an embodiment, the pixel electrode ADE may overlap the first to eighth edges E1, E2, E3, E4, E5, E6, E7, and E8 of the body part BP in a plan view.

In an embodiment, as shown in FIG. 5, a portion of an upper surface of the pixel electrode ADE adjacent to the first edge E1 may be substantially flat. In other words, as the first protrusion part PP1 protrudes from the first edge E1 to the boundary between the second light emitting area EA2 and the non-light emitting area NEA, the portion of the upper surface of the pixel electrode ADE adjacent to the first edge E1 may not include a step, i.e., may not have any stepped structure.

In an embodiment, although not shown, similarly, a portion of the upper surface of the pixel electrode ADE adjacent to the second edge E2 may be substantially flat. In other words, as the second protrusion part PP2 protrudes from the second edge E2 to the boundary between the second light emitting area EA2 and the non-light emitting area NEA, the portion of the upper surface of the pixel electrode ADE adjacent to the second edge E2 may not include a step.

In an embodiment, as shown in FIG. 6, a portion of the upper surface of the pixel electrode ADE adjacent to the seventh edge E7 may include a step or have a stepped structure. In such an embodiment, as described above, the conductive line CL may not be located between the seventh edge E7 and the boundary between the second light emitting area EA2 and the non-light emitting area NEA. Accordingly, a portion of an upper surface of the second via insulating layer VIA2 adjacent to the seventh edge E7 may include a step corresponding to a profile of the conductive line CL (e.g., the body part BP). Accordingly, the portion of the upper surface of the pixel electrode ADE disposed on the portion of the upper surface of the second via insulating layer VIA2 may also include a step corresponding to the step of the second via insulating layer VIA2. That is, the portion of the upper surface of the pixel electrode ADE adjacent to the seventh edge E7 may not be substantially flat.

In an embodiment, although not shown, each of portions of the upper surface of the pixel electrode ADE adjacent to the third to sixth edges E3, E4, E5, and E6 and the eighth edge E8, respectively, may include a step. In such an embodiment, as described above, the conductive line CL may not be located between the third to sixth edges E3, E4, E5, and E6 and the eighth edge E8 and the boundary between the second light emitting area EA2 and the non-light emitting area NEA. Accordingly, each of portions of the upper surface of the second via insulating layer VIA2 adjacent to the third to sixth edges E3, E4, E5, and E6 and the eighth edge E8, respectively, may include a step corresponding to the profile the conductive line CL (e.g., the body part BP). Accordingly, the portions of the upper surface of the pixel electrode ADE disposed on the portions of the upper surface of the second via insulating layer VIA2 may also include a step corresponding to the step of the second via insulating layer VIA2. That is, each of the portions of the upper surface of the pixel electrode ADE adjacent to the third to sixth edges E3, E4, E5, and E6 and the eighth edge E8, respectively, may not be substantially flat.

The light emitting layer EL may be disposed on the pixel electrode ADE in the pixel opening. The light emitting layer EL may include a material that emits light. In an embodiment, for example, the light emitting layer EL may include an organic light emitting material.

In an embodiment, functional layers such as a hole injection layer, a hole transport layer, an electron transport layer, and an electron injection layer may be additionally disposed above and/or below the light emitting layer EL.

The common electrode CTE may be disposed on the light emitting layer EL. The common electrode CTE may include a conductive material such as a metal, an alloy, a conductive metal nitride, a conductive metal oxide, or a transparent conductive material. The common electrode CTE may have a single-layer structure or a multi-layer structure including a plurality of conductive layers. In an embodiment, the common electrode CTE may continuously extend over a plurality of pixels.

In an embodiment, as described above, a step may be formed inside the second light emitting area EA2 according to the profile of the conductive line CL (e.g., the body part BP). The step may affect the light emitting layer EL and the common electrode CTE disposed on the pixel electrode ADE. That is, portions of an upper surface of the light emitting layer EL adjacent to the third to sixth edges E3, E4, E5, and E6 and the eighth edge E8, respectively, may have a stepped structure, and portions of an upper surface of the common electrode CTE adjacent to the third to sixth edges E3, E4, E5, and E6 and the eighth edge E8 respectively may have a stepped structure.

A configuration, an arrangement structure, and a connection structure of each of the driving element TR, the conductive line CL, the light emitting element LED, and the plurality of insulating layers described with reference to FIGS. 5 and 6 are only example, and may be variously changed according to embodiments.

The encapsulation layer ENC may be disposed on the light emitting element LED and cover the light emitting element LED. The encapsulation layer ENC may protect the light emitting element LED from external moisture, heat, shock, or the like. In an embodiment, although not shown, the encapsulation layer ENC may include a first inorganic encapsulation layer, an organic encapsulation layer disposed on the first inorganic encapsulation layer, and a second inorganic encapsulation layer disposed on the organic encapsulation layer.

The polarization layer POL may be disposed on the encapsulation layer ENC. The polarization layer POL may reduce reflection of external light of the display device DD. In an embodiment, for example, when external light passes through the polarization layer POL, is reflected from the below the polarization layer POL, and then passes through the polarization layer POL again, a phase of the external light passes through the polarization layer POL may be changed. Accordingly, destructive interference may occur due to a different phase of a reflected light from a phase of an incident light entering the polarization layer POL, and the reflection of external light may be reduced, thereby improving visibility of the display device DD.

In an embodiment, although not shown, a sensing layer may be additionally disposed between the encapsulation layer ENC and the polarization layer POL. The sensing layer may include a plurality of sensing electrodes and may sense a user's touch.

The window WIN may be disposed on the polarization layer POL. The window WIN may protect lower structures from external impurities, impact, or the like. In an embodiment, the window WIN may include flexible transparent glass or transparent plastic. In an embodiment, although not shown, functional layers such as a hard coating layer and an anti-fingerprint layer may be additionally disposed on the window WIN.

In a display device, a color shift (or color coordinate misalignment) in which different colors are viewed may occur according to a position and an azimuth angle of a user viewing the display device. This color shift is also called white angular dependency (WAD). In the white angular dependency, when white light is emitted from a display device, white light is viewed from a front, but color shift (greenish, bluish, reddish) is viewed from a side since a shift of wavelength due to a path difference of light.

In an embodiment, for example, where the polarization layer POL is disposed on the light emitting device LED, a luminance ratio at a specific azimuth angle may relatively increase by the polarization layer POL, and as a result, a luminance may be non-uniform for each azimuth angle. Accordingly, color shift (WAD) characteristics may become non-uniform according to the user's location and azimuth.

In an embodiment, light emitted from the portions of the upper surface of the pixel electrode AED having a stepped structure may have light emission characteristics of an inclined surface. In an embodiment, for example, a portion of light emitted from the portions of the upper surface of the pixel electrode AED having a stepped structure may be emitted by being twisted by an angle of the inclined surface. Therefore, a luminance ratio of light emitted from the portions of the upper surface of the pixel electrode AED having a stepped structure may increase compared to the portions of the upper surface of the pixel electrode AED which are substantially flat.

According to embodiments of the invention, the profile of the upper surface of the pixel electrode ADE in the light emitting area may be adjusted by adjusting protruding direction of each of the first protrusion part PP1 and the second protrusion part PP2 from the body part BP. Accordingly, a luminance ratio of light emitted from the pixel electrode ADE may be adjusted for each azimuth angle. In an embodiment, for example, by not defining protrusion parts in some directions corresponding to an azimuth angle for which a luminance ratio is desired to be increased, but selectively defining protrusion parts only in the other directions, a luminance ratio of emitted light may be selectively increased according to an azimuth angle. In such an embodiment, a luminance ratio may be selectively increased at an azimuth angle corresponding to some directions other than directions in which the protrusion parts protrude from the body part BP, respectively.

In such an embodiment, as described above, a luminance ratio of light emitted from the pixel electrode ADE at an azimuth angle other than the specific azimuthal angle at which a luminance ratio is increased by the polarization layer POL may be selectively increased through a stepped structure of the upper surface of the pixel electrode ADE. Therefore, even after the polarization layer POL is disposed on the light emitting element LED, luminance non-uniformity or color shift non-uniformity by azimuth angles caused by the polarization layer POL may be substantially decreased or effectively prevented.

In an embodiment, for example, where luminance increases at azimuth angle of 45 degrees and at azimuth angle of 225 degrees by the polarization layer POL, the overlapping portion OP of the conductive line CL may include the first protrusion part PP1 protruding from the body part BP toward the first direction DR1 and the second protrusion part PP2 protruding from the body part BP toward the second direction DR2. Accordingly, a luminance ratio may be selectively increased in azimuth angles corresponding to directions other than the first and second directions DR1 and DR2 in which the protrusion parts PP1 and PP2 protrude from the body part BP, respectively. Accordingly, a luminance ratio can be selectively increased at azimuth angles other than azimuth angle of 45 degrees and at azimuth angle of 225 degrees. Therefore, even after the polarization layer POL is disposed, luminance non-uniformity or color shift non-uniformity by azimuth angles may be substantially decreased or effectively prevented.

However, this is only an example. In such an embodiment, while the first protrusion part PP1 and the second protrusion part PP2 is opposite to each other with the center point CP therebetween, direction in which each of the first protrusion part PP1 and the second protrusion part PP2 protrudes is not particularly limited.

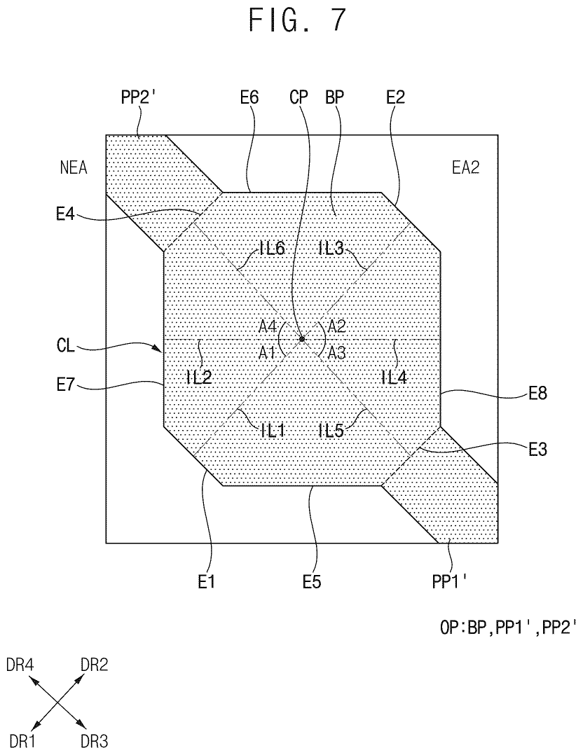

FIG. 7 is an enlarged view illustrating an enlarged second light emitting area of the display device of FIG. 1 according to an alternative embodiment.

In an embodiment, for example, where luminance increases at azimuth angle of 135 degrees and at azimuth angle of 315 degrees by the polarization layer POL, the overlapping portion OP of the conductive line CL may include the first protrusion part PP1′ protruding from the body part BP toward the third direction DR3 and the second protrusion part PP2′ protruding from the body part BP toward the fourth direction DR4.

In such an embodiment, the first protrusion part PP1′ may protrude from the third edge E3 of the body part BP to the boundary between the second light emitting area EA2 and the non-light emitting area NEA. Therefore, in a plan view, the overlapping portion OP of the conductive line CL may be connected to the boundary between the second light emitting area EA2 and the non-light emitting area NEA by the first protrusion part PP1′ in the third direction DR3 from the center point CP of the body part BP. That is, the conductive line CL may be located between the third edge E3 and the boundary between the second light emitting area EA2 and the non-light emitting area NEA.

In such an embodiment, the second protrusion part PP2′ may protrude from the fourth edge E4 to the boundary between the second light emitting area EA2 and the non-light emitting area NEA. Therefore, in a plan view, the overlapping portion OP of the conductive line CL may be connected to the boundary between the second light emitting area EA2 and the non-light emitting area NEA by the second protrusion part PP2′ in the fourth direction DR4 from the center point CP of the body part BP. That is, the conductive line CL may be located between the fourth edge E4 and the boundary between the second light emitting area EA2 and the non-light emitting area NEA.

In such an embodiment, separate protrusion parts may not protrude from the first edge E1, the second edge E2, and fifth to eighth edges E5, E6, E7, and E8. That is, the conductive line CL may not be located between the first edge E1, the second edge E2, and fifth to eighth edges E5, E6, E7, and E8 and the boundary between the second light emitting area EA2 and the non-light emitting area NEA.

Accordingly, a luminance ratio may be selectively increased in azimuth angles corresponding to directions other than the third and fourth directions DR3 and DR4 in which the protrusions PP1′ and PP2′ protrude from the body part BP, respectively. Accordingly, a luminance ratio may be selectively increased at azimuth angles other than azimuth angle of 135 degrees and at azimuth angle of 315 degrees. Therefore, even after the polarization layer POL is disposed, luminance non-uniformity or color shift non-uniformity by azimuth angles may be substantially decreased or effectively prevented.

In an embodiment, although not shown, where luminance increases at azimuth angle of 90 degrees and at azimuth angle of 270 degrees by the polarization layer POL, a first protrusion part may extend from the fifth edge E5 of the body part BP to the boundary between the second light emitting area EA2 and the non-light emitting area NEA, and a second protrusion part protrudes from the sixth edge E6 of the body part BP to the boundary between the second light emitting area EA2 and the non-light emitting area NEA.

In an embodiment, although not shown, where luminance increases at azimuth angle of 0 degrees and at azimuth angle of 180 degrees by the polarization layer POL, a first protrusion part may extend from the seventh edge E7 of the body part BP to the boundary between the second light emitting area EA2 and the non-light emitting area NEA, and a second protrusion part protrudes from the eight edge E8 of the body part BP to the boundary between the second light emitting area EA2 and the non-light emitting area NEA.

According to embodiments of the invention, the display device DD may include the conductive line CL disposed below the pixel electrode ADE. In such embodiments, the conductive line CL may pass through the light emitting area in a plan view, and include the overlapping portion OP overlapping the light emitting area. In addition, the overlapping portion OP may include the body part BP, the first protrusion part, and the second protrusion part, the body part BP may have an area smaller than an area of the light emitting area corresponding, and the first protrusion part and the second protruding part may protrude in opposite directions from the body part BP to the boundary between the light emitting area and the non-light emitting area, respectively.

Accordingly, in such embodiments, portions of the upper surface of the pixel electrode ADE adjacent to an edge of the body part BP from which the first protrusion part protrudes and an edge of the body part BP from which the second protrusion part protrudes, respectively, may be substantially flat. In such embodiments, a portion of the upper surface of the pixel electrode ADE adjacent to an edge of the body part BP where the first protrusion part and the second protrusion part do not protrude may have a stepped structure.

That is, a profile of the upper surface of the pixel electrode ADE in the light emitting area may be adjusted by adjusting a direction in which each of the first protrusion part and the second protrusion part protrude from the body part BP. Accordingly, a luminance ratio of light emitted from the pixel electrode ADE may be adjusted for each azimuth angle. Therefore, even after the polarization layer POL is disposed on the light emitting element LED, luminance non-uniformity or color shift non-uniformity by azimuth angles caused by the polarization layer POL may be substantially decreased or effectively prevented. Accordingly, display quality of the display device DD may be improved.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a substrate including a light emitting area and a non-light emitting area surrounding the light emitting area;
a conductive line disposed on the substrate to pass through the light emitting area in a plan view, wherein the conductive line includes an overlapping portion overlapping the light emitting area; and
a pixel electrode disposed on the conductive line and at least partially overlapping the overlapping portion of the conductive line, and
wherein the overlapping portion of the conductive line includes:
a body part having a polygonal planar shape and having an area smaller than an area of the light emitting area in the plan view;
a first protrusion part protruding in a first direction from the body part to a boundary between the light emitting area and the non-light emitting area in the plan view; and
a second protrusion part protruding in a second direction opposite to the first direction from the body part to the boundary between the light emitting area and the non-light emitting area in the plan view.

2. The display device of claim 1, wherein the first protrusion part and the second protrusion part be opposite to each other with a center point of the body part therebetween.

3. The display device of claim 2, wherein the overlapping portion of the conductive line is point symmetric with respect to the center point of the body part.

4. The display device of claim 1, wherein
the pixel electrode overlaps an edge of the body part in the plan view, and
a portion of an upper surface of the pixel electrode adjacent to an edge of the body part, from which the first protrusion part protrudes, and a portion of the upper surface of the pixel electrode adjacent to an edge of the body part, from which the second protrusion part protrudes, are substantially flat.

5. The display device of claim 4, wherein a portion of the upper surface of the pixel electrode adjacent to an edge of the body part, where the first protrusion part and the second protrusion part do not protrude, has a stepped structure.

6. The display device of claim 1, further comprising:
a first via insulating layer and a second via insulating layer, which are disposed between the substrate and the pixel electrode; and
a lower conductive layer disposed between the substrate and the first via insulating layer, and
wherein the conductive line is disposed between the first via insulating layer and the second via insulating layer, and is electrically connected to the pixel electrode through a contact hole defined in the second via insulating layer.

7. The display device of claim 6, wherein the conductive line is electrically connected to the lower conductive layer through a contact hole defined in the first via insulating layer.

8. The display device of claim 1, wherein the conductive line includes:
a data line which transmits a data voltage;
a power supply voltage line which transmits a power supply voltage; and
an initialization voltage line which transmits an initialization voltage.

9. The display device of claim 1, further comprising:
a light emitting layer disposed on the pixel electrode;
a common electrode disposed on the light emitting layer; and
a polarization layer disposed on the common electrode.

10. A display device comprising:
a substrate including a light emitting area and a non-light emitting area surrounding the light emitting area;
a conductive line disposed on the substrate to pass through the light emitting area in a plan view, wherein the conductive line includes an overlapping portion overlapping the light emitting area; and
a pixel electrode disposed on the conductive line and at least partially overlapping the overlapping portion of the conductive line, and
wherein the overlapping portion of the conductive line includes:
a body part having an octagonal planar shape and having an area smaller than an area of the light emitting area in the plan view;
a first protrusion part protruding in a first direction from a first edge of the body part to a boundary between the light emitting area and the non-light emitting area in the plan view; and
a second protrusion part protruding in a second direction opposite to the first direction from a second edge of the body part to the boundary between the light emitting area and the non-light emitting area in the plan view.

11. The display device of claim 10, wherein the first edge and the second edge are opposite to each other with a center point of the body part therebetween.

12. The display device of claim 11, wherein the overlapping portion of the conductive line is point symmetric with respect to the center point of the body part.

13. The display device of claim 11, wherein the body part includes:
a third edge located in a third direction perpendicular to both of the first direction and the second direction from the center point;
a fourth edge located in a fourth direction opposite to the third direction from the center point and opposite to the third edge with the center point therebetween;
a fifth edge connecting the first edge and the third edge;
a sixth edge connecting the second edge and the fourth edge and opposite to the fifth edge with the center point therebetween;
a seventh edge connecting the first edge and the fourth edge; and
an eighth edge connecting the second edge and the third edge and opposite to the seventh edge with the center point therebetween.

14. The display device of claim 13, wherein
a first imaginary line extending from the center point to the first edge and substantially perpendicular to the first edge is inclined by about 45 degrees in a counterclockwise direction from a second imaginary line extending from the center point to the seventh edge and substantially perpendicular to the seventh edge in the plan view, and
a third imaginary line extending from the center point to the second edge and substantially perpendicular to the second edge is inclined by about 45 degrees in the counterclockwise direction from a fourth imaginary line extending from the center point to the eighth edge and substantially perpendicular to the eighth edge in the plan view.

15. The display device of claim 14, wherein
a fifth imaginary line extending from the center point to the third edge and substantially perpendicular to the third edge is inclined by about 45 degrees in a clockwise direction from the fourth imaginary line in the plan view, and
a sixth imaginary line extending from the center point to the fourth edge and substantially perpendicular to the fourth edge is inclined by about 45 degrees in the clockwise direction from the second imaginary line in the plan view.

16. The display device of claim 13, wherein
the pixel electrode overlaps the first to eighth edges in the plan view, and
a portion of an upper surface of the pixel electrode adjacent to the first edge and a portion of the upper surface of the pixel electrode adjacent to the second edge are substantially flat.

17. The display device of claim 13, wherein each of portions of an upper surface of the pixel electrode adjacent to the third to eighth edges, respectively, have a stepped structure.

18. The display device of claim 10, further comprising:
a first via insulating layer and a second via insulating layer, which are disposed between the substrate and the pixel electrode; and
a lower conductive layer disposed between the substrate and the first via insulating layer, and
wherein the conductive line is disposed between the first via insulating layer and the second via insulating layer, is electrically connected to the pixel electrode through a contact hole defined in the second via insulating layer, and is electrically connected to the lower conductive layer through a contact hole defined in the first via insulating layer.

19. The display device of claim 10, wherein the conductive line includes:
a data line which transmits a data voltage;
a power supply voltage line which transmits a power supply voltage; and
an initialization voltage line which transmits an initialization voltage.

20. The display device of claim 10, further comprising:
a light emitting layer disposed on the pixel electrode;
a common electrode disposed on the light emitting layer; and
a polarization layer disposed on the common electrode.
